(19) United States
(12) Patent Application Publication
(10) Pub. No.: US 2026/0334256 A1
(43) Pub. Date: Oct. 22, 2026

(54) SEMICONDUCTOR PACKAGE INCLUDING AN INTERPOSER SUBSTRATE

(71) Applicant: Samsung Electronics Co., Ltd., Suwon-si (KR)

(72) Inventors: Hyeonjae KIM, Suwon-si (KR); Seung-Kwan RYU, Suwon-si (KR); Jihong PARK, Suwon-si (KR); Yukyung PARK, Suwon-si (KR)

(21) Appl. No.: 19/439,646

(22) Filed: Jan. 5, 2026

(30) Foreign Application Priority Data
Apr. 17, 2025 (KR) 10-2025-0050337
Jun. 9, 2025 (KR) 10-2025-0074824

(51) Int. Cl. H10W 70/63; H10W 74/10; H10W 90/26

(52) U.S. Cl. CPC H10W 70/635; H10W 74/141; H10W 90/26

(57) ABSTRACT

An example semiconductor package includes an interposer substrate and a first semiconductor chip on an upper surface of the interposer substrate. The interposer substrate includes a first sub-substrate and a second sub-substrate contacting the first sub-substrate vertically, the first sub-substrate includes a first core layer having a first surface and a second surface, a first through via penetrating the first core layer and having a diameter that decreases toward the second surface, and a first redistribution layer on the first surface, the second sub-substrate includes a second core layer having a third surface and a fourth surface, a second through via penetrating the second core layer and having a diameter that decreases toward the fourth surface, and a second redistribution layer on the third surface, the second surface and the fourth surface face each other, and the first through via contacts the second through via vertically.

### CROSS-REFERENCE TO RELATED APPLICATIONS

This application claims priority under 35 U.S.C. § 119 of Korean Patent Application Nos. 10-2025-0050337, filed on Apr. 17, 2025, and 10-2025-0074824, filed on Jun. 9, 2025, the entire contents of which are hereby incorporated by reference.

### BACKGROUND

With the development of electronic industry, demand for an electronic component having high functionality, high speed, high capacity, and small size is increasing. In response to such a trend, recently, packaging technology of mounting a plurality of semiconductor chips in one package has been developed.

An integrated circuit chip is packaged into a semiconductor package to have a suitable form to be installed in an electronic product. In general, in a semiconductor package, a semiconductor chip is mounted on a printed circuit board (PCB), and the semiconductor chip and the PCB are electrically connected to each other using bonding wires or bumps.

### SUMMARY

The present disclosure relates to a semiconductor package with improved electrical characteristics, a semiconductor package with improved thermal characteristics, and a method for manufacturing the same.

The objects of the present disclosure are not limited to the aforementioned object, but other objects not described herein will be clearly understood by those skilled in the art from the following description.

In some implementations, a semiconductor package includes an interposer substrate and a first semiconductor chip on an upper surface of the interposer substrate, where the interposer substrate includes a first sub-substrate and a second sub-substrate being vertically in contact with the first sub-substrate, the first sub-substrate includes a first core layer having a first surface and a second surface, a first through via penetrating the first core layer and having a diameter that decreases toward the second surface, and a first redistribution layer on the first surface of the first core layer, the second sub-substrate includes a second core layer having a third surface and a fourth surface, a second through via penetrating the second core layer and having a diameter that decreases toward the fourth surface, and a second redistribution layer on the third surface of the second core layer, the second surface of the first core layer and the fourth surface of the second core layer face each other, and the first through via and the second through via are vertically in contact with each other.

In some implementations, a semiconductor package includes an interposer substrate and a first semiconductor chip on an upper surface of the interposer substrate, where the interposer substrate includes a first core layer, a first redistribution layer on an upper surface of the first core layer, a second core layer on a lower surface of the first core layer, a second redistribution layer on a lower surface of the second core layer, an interposer through via penetrating the first core layer and the second core layer, and an interposer insulating layer interposed between the first core layer and the second core layer.

In some implementations, a semiconductor package includes a package substrate, an interposer substrate on an upper surface of the package substrate, and a first semiconductor chip on an upper surface of the interposer substrate, where the interposer substrate includes a first core layer, a first redistribution layer on an upper surface of the first core layer, a first through via penetrating the first core layer and protruding on to a lower surface of the first core layer, a second core layer on the lower surface of the first core layer, a second redistribution layer on a lower surface of the second core layer, a second through via penetrating the second core layer and protruding on to an upper surface of the second core layer, and an interposer insulating layer filling a space between the first core layer and the second core layer, and the first through via and the second through via are in contact with each other between the first core layer and the second core layer.

### BRIEF DESCRIPTION OF THE DRAWINGS

The accompanying drawings are included to provide a further understanding of the present disclosure, and are incorporated in and constitute a part of this specification. The drawings illustrate implementations of the present disclosure and, together with the description, serve to explain principles of the present disclosure.

FIG. 1 is a cross-sectional view illustrating an example of a semiconductor package.

FIG. 2 is an example enlarged view illustrating a portion, which is region N of FIG. 1, of a semiconductor package.

FIGS. 3 and 4 are enlarged views illustrating an example of a semiconductor package.

FIGS. 5, 6, 7, 8, 9, and 10 are cross-sectional views for describing an example of a method for manufacturing a semiconductor package.

### DETAILED DESCRIPTION

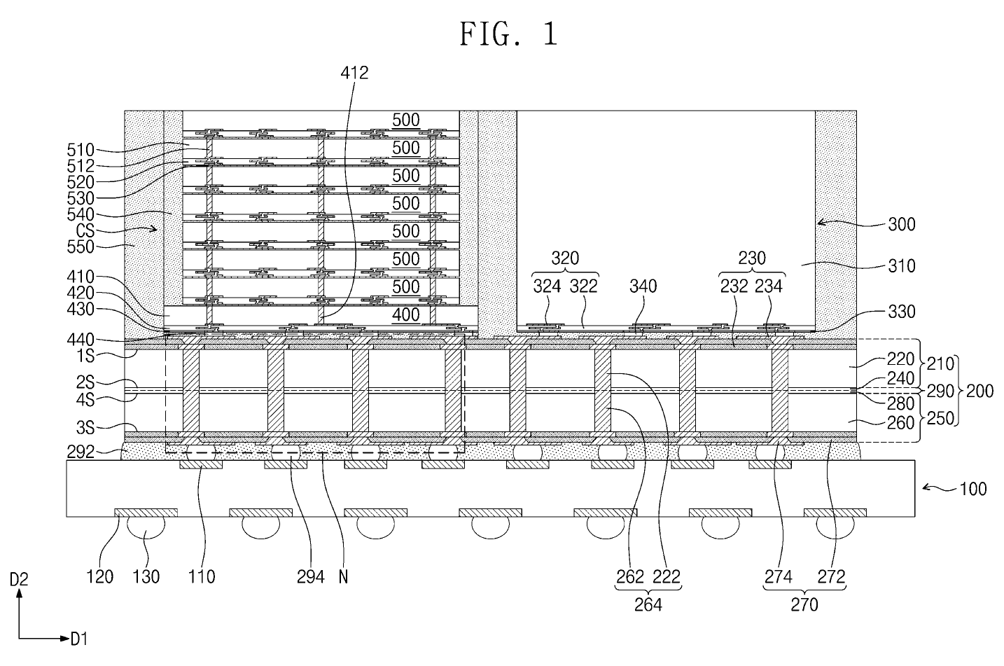

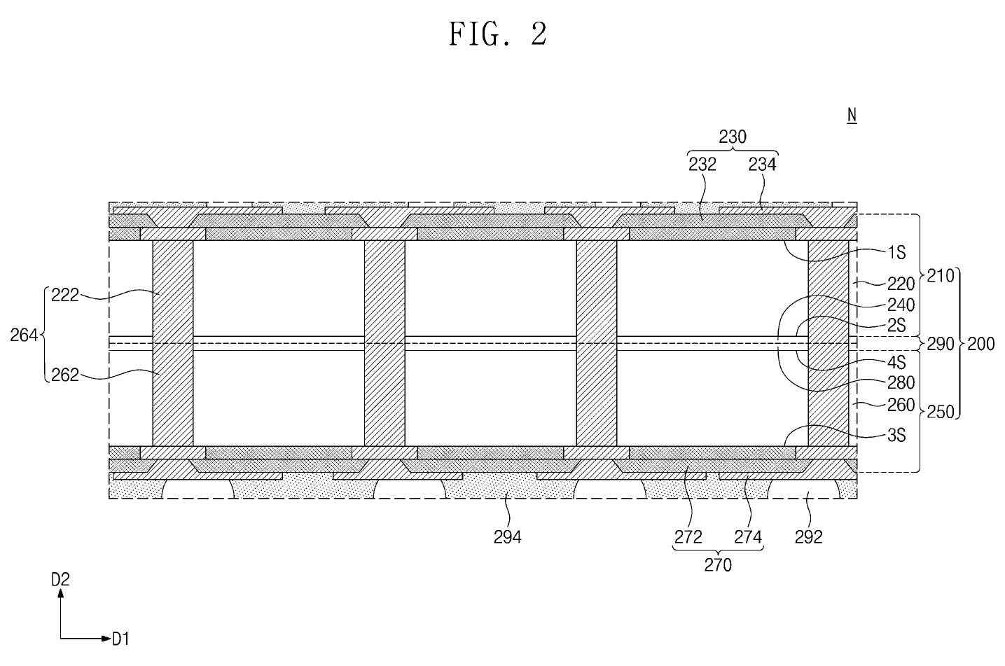

Hereinafter, a semiconductor package is described with reference to the drawings. FIG. 1 is a cross-sectional view illustrating an example of a semiconductor package. FIG. 2 is an example enlarged view illustrating a portion, which is region N of FIG. 1, of a semiconductor package. Referring to FIGS. 1 and 2, the semiconductor package may include a package substrate 100, an interposer substrate 200, a first semiconductor chip 300, and a chip stack CS. In the present disclosure, a first direction D1 may be defined as one direction parallel to an upper surface of the package substrate 100. A second direction D2 may be a direction perpendicular to the upper surface of the package substrate 100 and perpendicular to the first direction D1.

The package substrate 100 may be a printed circuit board (PCB). In this case, although not shown, the package substrate 100 may have an internal wiring pattern provided in the package substrate 100. For example, the package substrate 100 may have a structure in which an insulating pattern and the internal wiring pattern are alternately stacked. First package substrate pads 110 may be provided on the package substrate 100. The first package substrate pads 110 may be separate pads electrically connected to the internal wiring pattern or a portion of the internal wiring pattern exposed on the upper surface of the package substrate 100. The first package substrate pads 110 may be coplanar with the upper surface of the package substrate 100 and exposed on the package substrate 100. However, the present disclosure is not limited thereto, and the first package substrate pads 110 may protrude above the upper surface of the package substrate 100.

Second package substrate pads 120 and external connection terminals 130 may be provided on a lower surface of the package substrate 100. The second package substrate pads 120 may be separate pads arranged on the lower surface of the package substrate 100 and connected to the internal wiring pattern of the package substrate 100 or a portion of the conductive pattern exposed on the lower surface of the package substrate 100. The external connection terminals 130 may each be disposed on a lower surface of one of the second package substrate pads 120. The external connection terminals 130 may include a solder ball, a solder bump, or the like. The first package substrate pads 110 and the second package substrate pads 120 may include a conductive material such as metal.

The interposer substrate 200 may be provided on the package substrate 100. The interposer substrate 200 may include a first sub-substrate 210, a second sub-substrate 250, and an interposer insulating layer 290. The first sub-substrate 210 may include a first core layer 220 and a first redistribution layer 230. The first core layer 220 may have a flat plate shape. The first core layer 220 may include a first surface 1S and a second surface 2S. The first surface 1S and the second surface 2S may be parallel to the first direction D1. The first surface 1S and the second surface 2S may be opposed to each other. For example, the first surface 1S of the first core layer 220 may be an upper surface of the first core layer 220. The second surface 2S of the first core layer 220 may be a lower surface of the first core layer 220. The first core layer 220 may include a semiconductor material. For example, the first core layer 220 may include a silicon substrate. Alternatively, the first core layer 220 may include an insulating material. For example, the first core layer 220 may include an insulating polymer or glass. The first redistribution layer 230 may be provided on the first surface 1S of the first core layer 220. The first redistribution layer 230 may cover the first surface 1S of the first core layer 220. The first redistribution layer 230 may include one or more first wiring layers sequentially stacked on the first surface 1S of the first core layer 220. The first wiring layer may include a first insulating pattern 232 and a first wiring pattern 234. The first wiring pattern 234 of any one first wiring layer may be electrically connected to the first wiring pattern 234 of another adjacent first wiring layer. Hereinafter, the first insulating pattern 232 and the first wiring pattern 234 will be described with respect to one first wiring layer.

The first insulating pattern 232 may include an insulating polymer or a photosensitive polymer (PID). For example, the photosensitive polymer may include at least one of photosensitive polyimide, polybenzoxazole (PBO), phenol-based polymer or benzocyclobutene-based polymer.

The first wiring pattern 234 may be provided on the first insulating pattern 232. An upper surface of the first wiring pattern 234 may be exposed on the first insulating pattern 232. Alternatively, the first wiring pattern 234 may protrude above the first insulating pattern 232. The first wiring pattern 234 may horizontally extend on the first insulating pattern 232. The first wiring pattern 234 may be covered with the first insulating pattern 232 of another first wiring layer disposed on the first wiring pattern 234. As described above, the first wiring pattern 234 may be a pad portion or a line portion of the first wiring layer. That is, the first wiring pattern 234 may be a component for horizontal redistribution in the first redistribution layer 230. The first wiring pattern 234 may include a conductive material. For example, the first wiring pattern 234 may include copper (Cu).

A portion of the first wiring pattern 234 may have a damascene structure. For example, a portion of the first wiring pattern 234 may have a via protruding on to a lower surface of the portion of the first wiring pattern 234. The via may be a component for vertically connecting first wiring patterns 234 of first wiring layers adjacent to each other. For example, the via may extend from the lower surface of the first wiring pattern 234 and penetrate the first insulating pattern 232 to be connected to an upper surface of the first wiring pattern 234 of another first wiring layer located under the first insulating pattern 232. That is, an upper portion of the first wiring pattern 234 located on the first insulating pattern 232 may be a head portion which is used as a horizontal line or a pad, and the via of the first wiring pattern 234 may be a tail portion. A portion of the first wiring pattern 234 may have a T-shape. The head portion of the first wiring pattern 234 disposed at an uppermost end among the first wiring layers may correspond to first interposer substrate pads for mounting the chip stack CS and the first semiconductor chip 300 to be described later. The first wiring pattern 234 of a lowermost first wiring layer among the first wiring layers may not have a T-shape. The first wiring pattern 234 of the lowermost first wiring layer may have a line shape. In more detail, the first wiring pattern 234 of the lowermost first wiring layer may not have the via. The first wiring pattern 234 of the lowermost first wiring layer may be electrically connected to a first through via 222 to be described later.

The first sub-substrate 210 may include the first through via 222 penetrating the first core layer 220. The first through via 222 may penetrate the first core layer 220 in the second direction D2. The first through via 222 may extend from the first surface 1S of the first core layer 220 toward the second surface 2S of the first core layer 220. The first through via 222 may penetrate the first core layer 220 and protrude above the second surface 2S of the first core layer 220. An upper surface of the first through via 222 may be exposed on the first surface 1S of the first core layer 220. The first through via 222 may be electrically connected to the first redistribution layer 230. In more detail, the upper surface of the first through via 222 may be in contact with the first wiring pattern 234 of the lowermost first wiring layer. The first through via 222 may have a pillar shape. For example, the first through via 222 may have a cylindrical shape. A planar shape of the first through via 222 may be a circular shape. A ratio of diameter to height of the first through via 222 may be about 1:5 to about 1:15. In this case, the height of the first through via 222 may refer to a distance, in the second direction D2, from a lower surface of the first through via 222 to the upper surface of the first through via 222. The first through via 222 may include a conductive material. For example, the first through via 222 may include a metal material such as copper (Cu), aluminum (Al), silver (Ag), tin (Sn), gold (Au), nickel (Ni), lead (Pb), titanium (Ti) or an alloy thereof. The first through via 222 may be provided in plurality if necessary.

A first insulating layer 240 may be provided on the second surface 2S of the first core layer 220. The first insulating layer 240 may cover the second surface 2S of the first core layer 220. The first insulating layer 240 may cover the second surface 2S of the first core layer 220 and surround the first through via 222 protruding on to the second surface 2S of the first core layer 220. The lower surface of the first through via 222 may be exposed on the first insulating layer 240. The first insulating layer 240 may include an insulating material. The first insulating layer 240 may include silicon oxide (SiOx), silicon nitride (SiNx), etc.

The second sub-substrate 250 may be vertically in contact with the first sub-substrate 210. The second sub-substrate 250 may be provided on the second surface 2S of the first sub-substrate 210. The second sub-substrate 250 may include a second core layer 260 and a second redistribution layer 270. The second core layer 260 may have a flat plate shape. The second core layer 260 may include a third surface 3S and a fourth surface 4S. The third surface 3S and the fourth surface 4S may be parallel to the first direction D1. The third surface 3S and the fourth surface 4S may be opposed to each other. For example, the third surface 3S of the second core layer 260 may be the lower surface of the second core layer 260. The fourth surface 4S of the second core layer 260 may be the upper surface of the second core layer 260. A height of the second core layer 260 in the second direction D2 may be equal to a height of the first core layer 220 in the second direction D2, but the present disclosure is not limited thereto. A width of the second core layer 260 in the first direction D1 may be equal to a width of the first core layer 220 in the first direction D1, but the present disclosure is not limited thereto. The second core layer 260 may include a semiconductor material. For example, the second core layer 260 may include a silicon substrate. Alternatively, the second core layer 260 may include an insulating material. For example, the second core layer 260 may include an insulating polymer or glass.

The second redistribution layer 270 may be provided on the third surface 3S of the second core layer 260. The second redistribution layer 270 may cover the third surface 3S of the second core layer 260. The second redistribution layer 270 may include one or more second wiring layers sequentially stacked on the third surface 3S of the second core layer 260. The second wiring layer may include a second insulating pattern 272 and a second wiring pattern 274. The second wiring pattern 274 of any one second wiring layer may be electrically connected to the second wiring pattern 274 of another adjacent second wiring layer. Hereinafter, the second insulating pattern 272 and the second wiring pattern 274 will be described with respect to one second wiring layer.

The second insulating pattern 272 may include an insulating polymer or a photosensitive polymer (PID). For example, the photosensitive polymer may include at least one of photosensitive polyimide, polybenzoxazole (PBO), phenol-based polymer or benzocyclobutene-based polymer.

The second wiring pattern 274 may be provided on the second insulating pattern 272. The second wiring pattern 274 may be provided on a lower surface of the second insulating pattern 272. The second wiring pattern 274 may be exposed on the lower surface of the second insulating pattern 272. Alternatively, the second wiring pattern 274 may protrude above the lower surface of the second insulating pattern 272. The second wiring pattern 274 may horizontally extend on the lower surface of the second insulating pattern 272. The second wiring pattern 274 may be covered with the second insulating pattern 272 of another second wiring layer disposed under the second wiring pattern 274. As described above, the second wiring pattern 274 may be a pad portion or a line portion of the second wiring layer. That is, the second wiring pattern 274 may be a component for horizontal redistribution in the second redistribution layer 270. The second wiring pattern 274 may include a wiring pattern of a power distribution network or a power delivery network. In other words, the second wiring pattern 274 may include a line for delivering power supplied from the outside to an inside of the interposer substrate 200. The second wiring pattern 274 may include a conductive material. For example, the second wiring pattern 274 may include copper (Cu).

A portion of the second wiring pattern 274 may have a damascene structure. For example, a portion of the second wiring pattern 274 may have a via protruding on to an upper surface of the portion of the second wiring pattern 274. The via may be a component for vertically connecting second wiring patterns 274 of second wiring layers adjacent to each other. For example, the via may extend from the upper surface of the second wiring pattern 274 and penetrate the second insulating pattern 272 to be connected to a lower surface of the second wiring pattern 274 of another second wiring layer located on the second insulating pattern 272. That is, a lower portion of the second wiring pattern 274 located under the second insulating pattern 272 may be a head portion which is used as a horizontal line or a pad, and the via of the second wiring pattern 274 may be a tail portion. A portion of the second wiring pattern 274 may have an inverted T-shape. The head portion of the second wiring pattern 274 of a lowermost second wiring layer among the second wiring layers may correspond to second interposer substrate pads for being mounted on the package substrate 100. The second wiring pattern 274 of an uppermost second wiring layer among the second wiring layers may not have an inverted T-shape. The second wiring pattern 274 of the uppermost second wiring layer may have a line shape. In more detail, the second wiring pattern 274 of the uppermost second wiring layer may not have the via. The second wiring pattern 274 of the uppermost second wiring layer may be electrically connected to a second through via 262 to be described later.

The second sub-substrate 250 may include the second through via 262 penetrating the second core layer 260. The second through via 262 may penetrate the second core layer 260 in the second direction D2. The second through via 262 may extend from the third surface 3S of the second core layer 260 toward the fourth surface 4S of the second core layer 260. The second through via 262 may penetrate the second core layer 260 and protrude above the fourth surface 4S of the second core layer 260. A lower surface of the second through via 262 may be exposed on the third surface 3S of the second core layer 260. The second through via 262 may be electrically connected to the second redistribution layer 270. In more detail, the lower surface of the second through via 262 may be in contact with the second wiring pattern 274 of the uppermost second wiring layer.

The second through via 262 may have a pillar shape. For example, the second through via 262 may have a cylindrical shape. A planar shape of the second through via 262 may be a circular shape. The planar shape of the second through via 262 may be the same as the planar shape of the first through via 222. A diameter of the second through via 262 may be equal to the diameter of the first through via 222. A ratio of the diameter to height of the second through via 262 may be about 1:5 to about 1:15. In this case, the height of the second through via 262 may refer to a distance, in the second direction D2, from the lower surface of the second through via 262 to an upper surface of the second through via 262. For example, the height of the second through via 262 may be equal to the height of the first through via 222. The second through via 262 may include a conductive material. For example, the second through via 262 may include a metal material such as copper (Cu), aluminum (Al), silver (Ag), tin (Sn), gold (Au), nickel (Ni), lead (Pb), titanium (Ti) or an alloy thereof. The second through via 262 may be provided in plurality if necessary.

The second through via 262 may be disposed on the lower surface of the first through via 222. The first through via 222 and the second through via 262 may be aligned with each other in the second direction D2. The second through via 262 may be vertically in contact with the first through via 222. The first through via 222 and the second through via 262 may be in contact with each other between the first core layer 220 and the second core layer 260. In a plan view, the first through via 222 may overlap the second through via 262. FIGS. 1 and 2 illustrate that the first through via 222 and the second through via 262 completely overlap each other, but the present disclosure is not limited thereto. The first through via 222 and the second through via 262 may not completely overlap each other. At least a portion of the first through via 222 may overlap at least a portion of the second through via 262. In other words, in a cross-sectional view, a side surface of the first through via 222 and a side surface of the second through via 262 may be spaced apart from each other in the first direction D1.

A second insulating layer 280 may be provided on the fourth surface 4S of the second core layer 260. The second insulating layer 280 may cover the fourth surface 4S of the second core layer 260. The second insulating layer 280 may cover the fourth surface 4S of the second core layer 260 and surround the second through via 262 protruding on to the fourth surface 4S of the second core layer 260. The upper surface of the second through via 262 may be exposed on the second insulating layer 280. The second insulating layer 280 may include an insulating material. The second insulating layer 280 may include silicon oxide (SiOx), silicon nitride (SiNx), etc.

The second through via 262 may be electrically connected to the first through via 222 on an interface between the first sub-substrate 210 and the second sub-substrate 250. The first wiring pattern 234 may be electrically connected to the second wiring pattern 274 through the first through via 222 and the second through via 262. The second through via 262 may be in contact with the lower surface of the first through via 222. The first through via 222 may be bonded to the second through via 262. In this case, the first through via 222 and the second through via 262 may be hybrid bonded. In the present disclosure, hybrid bonding refers to bonding for fusing two components including homogeneous materials at an interface between the two components. For example, the first through via 222 and the second through via 262 which are bonded to each other may have a continuous structure, and an interface between the first through via 222 and the second through via 262 may not be visible. The first through via 222 and the second through via 262 may include the same material and may be provided as one component. That is, the first through via 222 and the second through via 262 may be combined and integrally formed.

In other words, the first through via 222 and the second through via 262 may be combined and form one interposer through via 264. The interposer through via 264 may simultaneously penetrate the first core layer 220 and the second core layer 260. The interposer through via 264 may electrically connect the first redistribution layer 230 and the second redistribution layer 270. A ratio of diameter to height of the interposer through via 264 may be about 1:10 to about 1:30. In this case, the height of the interposer through via 264 may refer to a distance, in the second direction D2, from the lower surface of the second through via 262 to the upper surface of the first through via 222. Since the first through via 222 and the second through via 262 are hybrid bonded and constitute the interposer through via 264, the interposer through via 264 with large aspect ratio may be provided. However, the present disclosure is not limited thereto. The first through via 222 and the second through via 262 may include different materials and may not have a continuous structure.

The first insulating layer 240 and the second insulating layer 280 may be in contact with each other on an interface between the first sub-substrate 210 and the second sub-substrate 250. In a plan view, the first insulating layer 240 and the second insulating layer 280 may overlap each other. The first insulating layer 240 and the second insulating layer 280 may be bonded to each other on the interface between the first sub-substrate 210 and the second sub-substrate 250. In this case, the first insulating layer 240 and the second insulating layer 280 may be hybrid bonded. For example, the first insulating layer 240 and the second insulating layer 280 which are bonded to each other may have a continuous structure, and an interface between the first insulating layer 240 and the second insulating layer 280 may not be visible. The first insulating layer 240 and the second insulating layer 280 may include the same material and may be provided as one component. That is, the first insulating layer 240 and the second insulating layer 280 may be combined and form one interposer insulating layer 290. The interposer insulating layer 290 may be interposed between the first core layer 220 and the second core layer 260. The interposer insulating layer 290 may fill a space between the first core layer 220 and the second core layer 260. The interposer insulating layer 290 may surround the interposer through via 264 between the first core layer 220 and the second core layer 260. A height of the interposer insulating layer 290 in the second direction D2 may be about 0.1 micrometers to about 3 micrometers. However, the present disclosure is not limited thereto. The first insulating layer 240 and the second insulating layer 280 may include different materials and may not have a continuous structure. For example, the first insulating layer 240 and the second insulating layer 280 may each be an individual component.

Substrate connection terminals 294 may be provided on a lower surface of the second sub-substrate 250. The substrate connection terminal 294 may be disposed on the second interposer substrate pads provided on the lower surface of the second sub-substrate 250. The substrate connection terminals 294 may include a solder ball, a solder bump or the like.

Lower surfaces of the substrate connection terminals 294 of the interposer substrate 200 may be in contact with upper surfaces of the first package substrate pads 110. The interposer substrate 200 may be electrically connected to the package substrate 100 through the substrate connection terminal 294. The first redistribution layer 230 may be electrically connected to the substrate connection terminal 294 through the first through via 222, the second through via 262, and the second redistribution layer 270. An underfill layer 292 may be provided between the interposer substrate 200 and the package substrate 100. The underfill layer 292 may fill a space between the interposer substrate 200 and the package substrate 100 and surround the substrate connection terminal 294.

The first semiconductor chip 300 may be provided on the interposer substrate 200. The first semiconductor chip 300 may be provided face-down on the interposer substrate 200. The first semiconductor chip 300 may include a first semiconductor substrate 310. The first semiconductor substrate 310 may have an active surface and an inactive surface. Hereinafter, in the present disclosure, an active surface may be defined as a surface on which an integrated element or integrated circuits are formed in a semiconductor chip, and an inactive surface may be defined as an opposite surface of the active surface. A lower surface of the first semiconductor substrate 310 may be the active surface of the first semiconductor substrate 310. The first semiconductor substrate 310 may include a semiconductor material. For example, the first semiconductor substrate 310 may include silicon (Si). An integrated element or integrated circuits may be provided on the active surface of the first semiconductor substrate 310, that is, the lower surface of the first semiconductor substrate 310. The integrated element or the integrated circuits may include a logic circuit. That is, the first semiconductor chip 300 may be a logic chip.

A first chip wiring layer 320 may be provided on the active surface of the first semiconductor substrate 310. The first chip wiring layer 320 may have a first chip insulating pattern 322 and a first chip wiring pattern 324 provided in the first chip insulating pattern 322. The first chip insulating pattern 322 may cover the integrated element or the integrated circuits on a lower surface of the first semiconductor chip 300. The first chip wiring pattern 324 may be connected to the integrated element or the integrated circuits which are formed on the first semiconductor substrate 310. The first chip wiring pattern 324 may include a conductive material such as metal. For example, the first chip wiring pattern 324 may include copper (Cu). The first chip insulating pattern 322 may include oxide such as silicon oxide (SiOx).

The first semiconductor chip 300 may further include first chip pads provided on a lower surface of the first semiconductor chip 300. The first chip pads may be a portion of the first chip wiring pattern 324 protruding on to the lower surface of the first semiconductor chip 300 or separate pads arranged on a lower surface of the first chip insulating pattern 322 and connected to the first chip wiring pattern 324. A third insulating layer 330 may be provided on the active surface of the first semiconductor substrate 310. The third insulating layer 330 may cover the active surface of the first semiconductor substrate 310. The third insulating layer 330 may surround the first chip pads on the lower surface of the first semiconductor chip 300. The first chip pads may be exposed on a lower surface of the third insulating layer 330. The third insulating layer 330 may include silicon oxide (SiOx), silicon nitride (SiNx), etc.

First chip connection terminals 340 such as solder balls or solder bumps may be provided on lower surfaces of the first chip pads. One end of each of the first chip connection terminals 340 may be in contact with the first chip pads. The first chip connection terminals 340 may be electrically connected to the first chip wiring pattern 324 in the first semiconductor chip 300. The first semiconductor chip 300 may be mounted on the interposer substrate 200 by using the first chip connection terminals 340. The other end of each of the first chip connection terminals 340 may be in contact with the interposer substrate 200. In detail, the other end of each of the first chip connection terminals 340 may be electrically connected to the first interposer substrate pads of the interposer substrate 200. The first chip connection terminals 340 may be provided between an upper surface of the interposer substrate 200 and the lower surface of the first semiconductor chip 300 and may connect the interposer substrate 200 and the first semiconductor chip 300. The first chip wiring pattern 324 may be electrically connected to the interposer substrate 200 through the first chip pads and the first chip connection terminals 340.

The chip stack CS may be provided on the upper surface of the interposer substrate 200. The chip stack CS may be spaced apart from the first semiconductor chip 300 in the first direction D1 or an opposite direction of the first direction D1 on the interposer substrate 200. The chip stack CS may include a base chip 400, second semiconductor chips 500 stacked on the base chip 400, and a first molding layer 540 surrounding the second semiconductor chips 500.

The base chip 400 may be provided face-down on the interposer substrate 200. The base chip 400 may include a base substrate 410. The base substrate 410 may be a semiconductor substrate. For example, the base substrate 410 may be a wafer-level semiconductor substrate made of semiconductor such as silicon (Si). A lower surface of the base substrate 410 may be an active surface of the base substrate 410. In detail, an integrated element or integrated circuits may be provided on the active surface of the base substrate 410, that is, the lower surface of the base substrate 410. For example, the integrated element or the integrated circuits may include a memory circuit. That is, the base chip 400 may be a memory chip such as DRAM, SRAM, MRAM or flash memory. Alternatively, the integrated element or the integrated circuits may include a logic circuit. In this case, the base chip 400 may be a logic chip.

The base chip 400 may include a base wiring layer 420 and a base through via 412. The base wiring layer 420 may be provided on a lower surface of the base chip 400. The base wiring layer 420 may include the integrated element or the integrated circuit. The base through via 412 may penetrate the base chip 400 in the second direction D2. The base through via 412 and the base wiring layer 420 may be electrically connected. The base through via 412 may be provided in plurality if necessary.

The base chip 400 may further include base pads, a fourth insulating layer 430, and base connection terminals 440. The base pads may be pads arranged on the lower surface of the base chip 400 and connected to the base wiring layer 420 of the base chip 400. The base pads may be electrically connected to the integrated element or the integrated circuit. The fourth insulating layer 430 covering the lower surface of the base chip 400 may be provided. The fourth insulating layer 430 may cover the lower surface of the base chip 400. The fourth insulating layer 430 may surround the base pads on the lower surface of the base chip 400. The base pads may be exposed on a lower surface of the fourth insulating layer 430. The fourth insulating layer 430 may include silicon oxide (SiOx), silicon nitride (SiNx), etc. The base connection terminals 440 may be disposed on a lower surfaces of the base pads corresponding to the base connection terminals 440, respectively. Each of the base connection terminals 440 may be a solder ball or a solder bump. The base connection terminals 440 may be electrically connected to the integrated element or the integrated circuit.

A second semiconductor chip 500 may be provided on the base chip 400. A width of the second semiconductor chip 500 may be smaller than a width of the base chip 400. Thicknesses of the second semiconductor chip 500 and the base chip 400 of the chip stack CS may be smaller than a thickness of the first semiconductor chip 300.

The second semiconductor chip 500 may be provided face-down on the interposer substrate 200. The second semiconductor chip 500 may include a second semiconductor substrate 510. The second semiconductor substrate 510 may be a semiconductor substrate. For example, the second semiconductor substrate 510 may include silicon (Si). A lower surface of the second semiconductor substrate 510 may be an active surface. In detail, an integrated element or integrated circuits may be provided on the active surface of the second semiconductor substrate 510, that is, the lower surface of the second semiconductor substrate 510. For example, the integrated element or the integrated circuits may include a memory circuit. That is, the second semiconductor chip 500 may be a memory chip such as DRAM, SRAM, MRAM or flash memory.

The second semiconductor chip 500 may include a second chip wiring layer 520 and a second chip through via 512. The second chip wiring layer 520 may be provided on the active surface of the second semiconductor substrate 510. The second chip wiring layer 520 may include the integrated element or the integrated circuit. The second chip through via 512 may penetrate the second semiconductor chip 500 in the second direction D2. The second chip through via 512 and the second chip wiring layer 520 may be electrically connected. Connection bumps 530 may be provided on a lower surface of the second semiconductor chip 500. The connection bumps 530 may include a solder ball, a solder bump, or the like. The connection bumps 530 may electrically connect the base chip 400 and the second semiconductor chip 500 between the base chip 400 and the second semiconductor chip 500. The connection bumps 530 may be electrically connected to the integrated element or the integrated circuit of the second chip wiring layer 520.

The second semiconductor chip 500 may be provided in plurality. For example, a plurality of second semiconductor chips 500 may be stacked on the base chip 400. Eight to thirty-two second semiconductor chips 500 may be stacked. The connection bumps 530 may be provided between the second semiconductor chips 500. The connection bumps 530 may be connected to the second chip through via 512 of another second semiconductor chip 500 disposed under the connection bumps 530. Although not shown, adhesive layers may be provided between the second semiconductor chips 500. The adhesive layers may include a non-conductive film (NCF). The adhesive layers may surround the connection bumps 530 between the second semiconductor chips 500 and may prevent electrical short circuit between the connection bumps 530. FIG. 2 illustrates that the second semiconductor chips 500 are connected using the connection bumps 530, but the present disclosure is not limited thereto. In some implementations, the second semiconductor chips 500 may be directly connected to each other. For example, the second chip through via 512 of the second semiconductor chips 500 may be directly connected to a wiring pattern of the second chip wiring layer 520 of another second semiconductor chip 500 disposed on the second chip through via 512.

A thickness of an uppermost second semiconductor chip 500 may be equal to or greater than a thickness of each of other second semiconductor chips 500 arranged under the uppermost second semiconductor chip 500. The uppermost second semiconductor chip 500 may not include the second chip through via 512.

The first molding layer 540 may be disposed on an upper surface of the base chip 400. The first molding layer 540 may cover the upper surface of the base chip 400. The first molding layer 540 may surround the second semiconductor chips 500. An upper surface of the first molding layer 540 may be coplanar with an upper surface of the uppermost second semiconductor chip 500. The first molding layer 540 may include an insulating polymer material. For example, the first molding layer 540 may include an epoxy molding compound (EMC).

The chip stack CS may be mounted on the interposer substrate 200. For example, the chip stack CS may be connected to the first interposer substrate pads of the interposer substrate 200 through the base connection terminals 440 of the base chip 400. The base connection terminals 440 may be in contact with the upper surfaces of the first interposer substrate pads and a lower surface of the base wiring layer 420 and electrically connect the chip stack CS and the interposer substrate 200.

A second molding layer 550 may be provided on the interposer substrate 200. The second molding layer 550 may cover the upper surface of the interposer substrate 200. The second molding layer 550 may surround the first semiconductor chip 300 and the chip stack CS on the interposer substrate 200. The second molding layer 550 may fill a space between the first semiconductor chip 300 and the chip stack CS. An upper surface of the second molding layer 550 may be coplanar with an upper surface of the first semiconductor chip 300 and an upper surface of the chip stack CS. The second molding layer 550 may include an insulating material. For example, the second molding layer 550 may include an epoxy molding compound (EMC).

The chip stack CS and the first semiconductor chip 300 may be electrically connected to the package substrate 100 along the first sub-substrate 210 and the second sub-substrate 250 of the interposer substrate 200. The interposer substrate 200 may redistribute the chip stack CS and the first semiconductor chip 300 between the chip stack CS and the package substrate 100 and between the first semiconductor chip 300 and the package substrate 100.

The first sub-substrate 210 and the second sub-substrate 250 may be hybrid bonded in the interposer substrate 200 of the semiconductor package. In this case, the second sub-substrate 250 may include a power distribution network or a power delivery network. The first sub-substrate 210 may not include a power distribution network or a power delivery network. Since a wiring pattern for delivering power is located close to a lower surface of the interposer substrate 200, the semiconductor package with improved power distribution and easy thermal management may be provided.

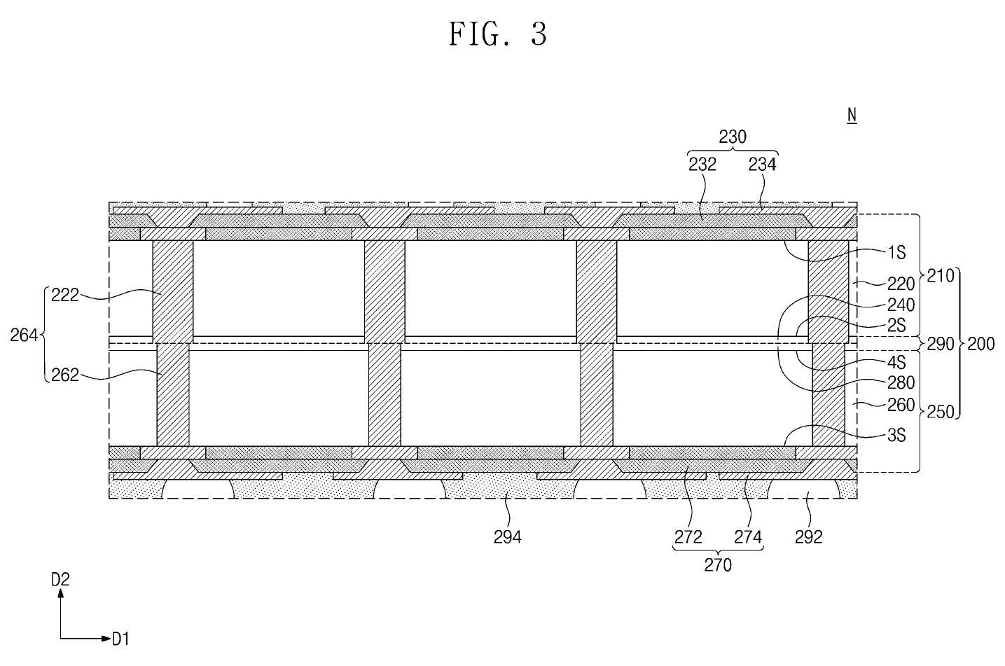

FIG. 3 is a cross-sectional view illustrating an example of a semiconductor package. Referring to FIG. 3, unlike FIGS. 1 and 2, a diameter of the first through via 222 and a diameter of the second through via 262 may be different from each other. In more detail, a diameter of a lower surface of the first through via 222 may be greater than a diameter of an upper surface of the second through via 262 at a contact surface between the first through via 222 and the second through via 262 or a contact surface between the first insulating layer 240 and the second insulating layer 280. Alternatively, a diameter of the lower surface of the first through via 222 may be smaller than a diameter of the upper surface of the second through via 262. Hereinafter, for convenience of description, description will be provided with respect to the implementation of FIG. 3. The second through via 262 may be disposed on the lower surface of the first through via 222. More specifically, the second through via 262 may be disposed on a center portion of the lower surface of the first through via 222. In a plan view, the second through via 262 may overlap the first through via 222. The upper surface of the second through via 262 may be in contact with the lower surface of the first through via 222. At least a portion of the lower surface of the first through via 222 may vertically overlap at least a portion of the upper surface of the second through via 262. More specifically, the entire upper surface of the second through via 262 may be in contact with the lower surface of the first through via 222. The first through via 222 and the second through via 262 may be hybrid bonded and constitute one interposer through via 264. In other words, a diameter of the interposer through via 264 may not be constant. The diameter of the interposer through via 264 may decrease discontinuously at a point between the first core layer 220 and the second core layer 260. The point may be located between the second surface 2S of the first core layer 220 and the fourth surface 4S of the second core layer 260.

Since the diameter of the first through via 222 is greater than the diameter of the second through via 262, the entire upper surface of the second through via 262 may be in contact with the entire lower surface of the first through via 222 even if the center of the upper surface of the second through via 262 and the center of the lower surface of the first through via 222 are not aligned with each other. Accordingly, the first through via 222 and the second through via 262 may be easily connected.

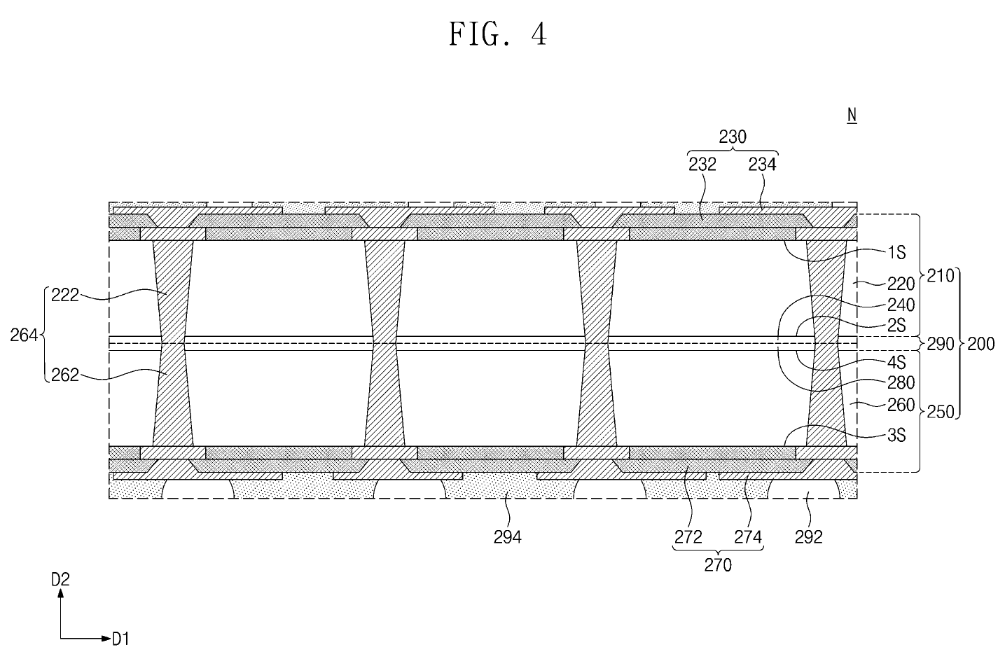

FIG. 4 is a cross-sectional view illustrating an example of a semiconductor package. Referring to FIG. 4, unlike FIGS. 1 and 2, a diameter of each of the first through via 222 and the second through via 262 may not be constant according to height. In more detail, the diameter of the first through via 222 may decrease in a direction from the first surface 1S of the first core layer 220 to the second surface 2S of the first core layer 220. For example, the first through via 222 may have a tapered shape in which the diameter of the first through via 222 decreases toward the second sub-substrate 250. The diameter of the second through via 262 may decrease in a direction from the third surface 3S of the second core layer 260 to the fourth surface 4S of the second core layer 260. For example, the second through via 262 may have a tapered shape in which the diameter of the second through via 262 decreases toward the first sub-substrate 210. In other words, the diameter of the first through via 222 may decrease in a direction to the second through via 262, and the diameter of the second through via 262 may decrease in a direction to the first through via 222.

The second through via 262 may be disposed on a lower surface of the first through via 222. The first through via 222 and the second through via 262 may be aligned with each other in the second direction D2. The lower surface of the first through via 222 and an upper surface of the second through via 262 may be in contact with each other. The first through via 222 and the second through via 262 may be hybrid bonded and constitute the interposer through via 264. The interposer through via 264 may have an hourglass shape. In other words, a diameter of the interposer through via 264 may increase as being farther away from a point in the second direction D2 and in an opposite direction of the second direction D2. The point may be located between the second surface 2S of the first core layer 220 and the fourth surface 4S of the second core layer 260.

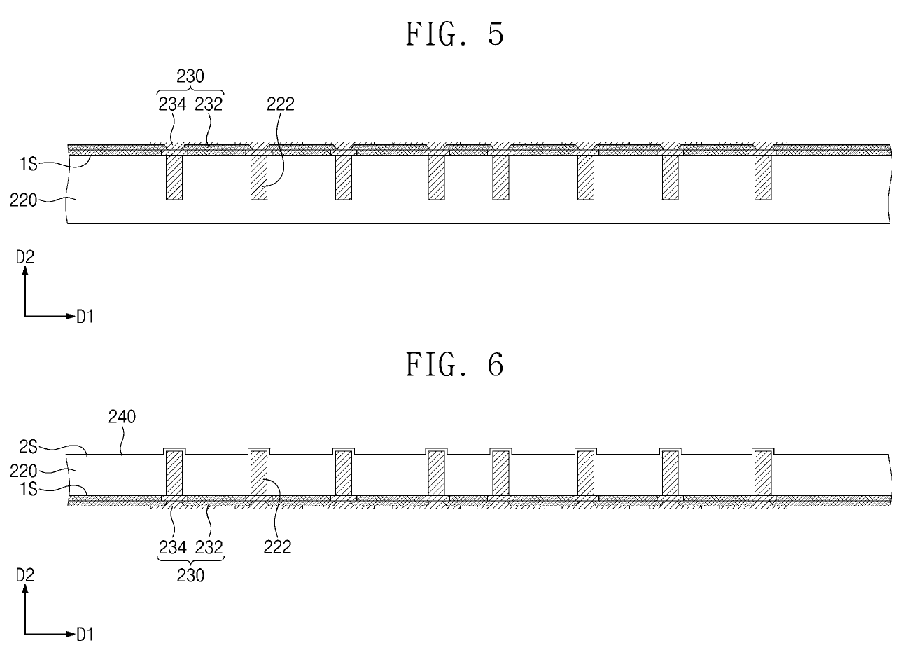

FIGS. 5, 6, 7, 8, 9, and 10 are cross-sectional views illustrating an example of a method for manufacturing a semiconductor package. Referring to FIG. 5, a first core layer 220 may be provided. Holes vertically penetrating at least a portion of the first core layer 220 from a first surface 1S of the first core layer 220 may be formed. A first through via 222 may be formed by filling the holes with a conductive material. Thereafter, a first redistribution layer 230 may be formed on the first surface 1S of the first core layer 220. For example, one first insulating pattern 232 may be formed by forming an insulating layer on the first surface 1S of the first core layer 220 and then patterning the insulating layer. One first wiring pattern 234 may be formed by forming a conductive layer on the first insulating pattern 232 and then patterning the conductive layer. The process of forming the first insulating pattern 232 and the first wiring pattern 234 may be repeatedly performed. A plurality of upper insulating patterns 232 and upper wiring patterns 234 which are formed may constitute the first redistribution layer 230 described above with reference to FIG. 1.

Referring to FIG. 6, a resultant structure of FIG. 5 may be turned upside down. The resultant structure may be disposed such that the first surface 1S of the first core layer 220 is located at the bottom. Thereafter, an upper surface of the first core layer 220 may be ground. The first through via 222 may protrude above the ground upper surface of the first core layer 220. The ground upper surface of the first core layer 220 may correspond to the second surface 2S of the first core layer 220 described with reference to FIGS. 1 and 2. The second surface 2S of the first core layer 220 may be at a vertical level lower than that of an upper surface of the first through via 222. A first insulating layer 240 may be formed on the second surface 2S of the first core layer 220. The first insulating layer 240 may uniformly cover the second surface 2S of the first core layer 220 and an upper end of the first through via 222 exposed on the first core layer 220. The first insulating layer 240 may include silicon oxide (SiOx), silicon nitride (SiNx), etc.

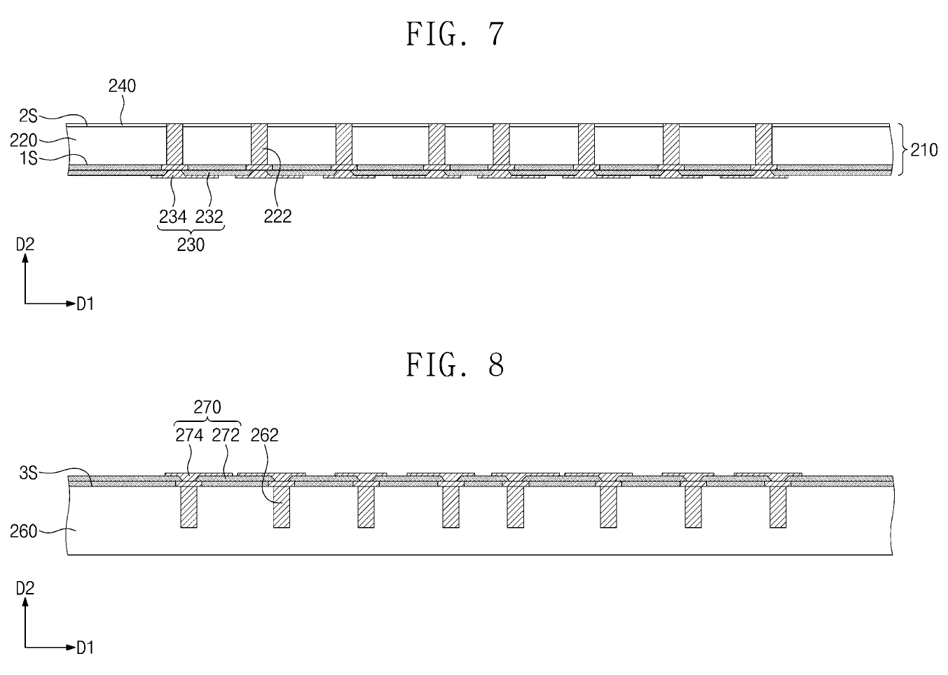

Referring to FIG. 7, a grinding process may be performed on a resultant structure of FIG. 6. A portion of the first insulating layer 240 and a portion of the first through via 222 may be removed through the grinding process. The grinding process may be performed until a vertical level of an upper surface of the first insulating layer 240 is the same as that of an upper surface of the first through via 222. The upper surface of the first through via 222 may be exposed on the upper surface of the first insulating layer 240. As described above, a first sub-substrate 210 may be formed.

Referring to FIG. 8, a second core layer 260 may be provided. Holes penetrating at least a portion of the second core layer 260 from a third surface 3S of the second core layer 260 may be formed. A second through via 262 may be formed by filling the holes with a conductive material. Thereafter, a second redistribution layer 270 may be formed on the second core layer 260. For example, one second insulating pattern 272 may be formed by forming an insulating layer on the third surface 3S of the second core layer 260 and then patterning the insulating layer. One second wiring pattern 274 may be formed by forming a conductive layer on the second insulating pattern 272 and then patterning the conductive layer. The process of forming the second insulating pattern 272 and the second wiring pattern 274 described above may be repeatedly performed. A plurality of second insulating patterns 272 and second wiring patterns 274 which are formed may constitute the second redistribution layer 270 described above with reference to FIG. 1.

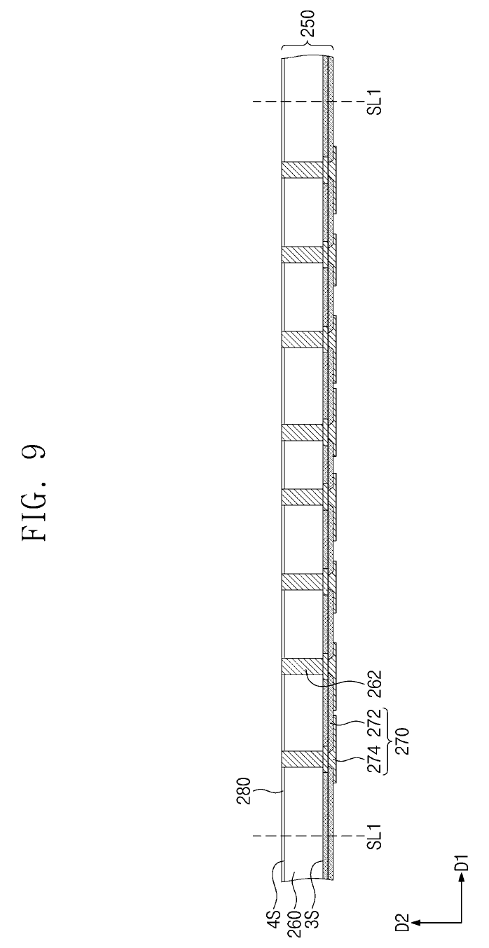

Referring to FIG. 9, a resultant structure of FIG. 8 may be turned upside down. The resultant structure may be disposed such that the third surface 3S of the second core layer 260 is located at the bottom. An upper surface of the second core layer 260 may be ground. Although not shown, the second through via 262 may protrude above the ground upper surface of the second core layer 260. The ground upper surface of the second core layer 260 may correspond to the fourth surface 4S of the second core layer 260 described with reference to FIGS. 1 and 2. The fourth surface 4S of the second core layer 260 may be at a vertical level lower than that of an uppermost end of the second through via 262. Thereafter, a second insulating layer 280 may be formed on the second core layer 260. A process of forming the second insulating layer 280 may be substantially the same as the process of forming the first insulating layer 240 described with reference to FIGS. 6 and 7. For example, the second insulating layer 280 may cover the fourth surface 4S of the second core layer 260 and the second through via 262 exposed on the second core layer 260. Thereafter, a grinding process may be performed. The grinding process may be performed until a vertical level of an upper surface of the second insulating layer 280 is the same as that of an upper surface of the second through via 262. The upper surface of the second through via 262 may be exposed on the upper surface of the second insulating layer 280.

Thereafter, a plurality of substrates may be formed by performing a sawing process along a first sawing line SL1. The substrates which are separated from each other through the sawing process may each correspond to the second sub-substrate 250 of FIG. 1.

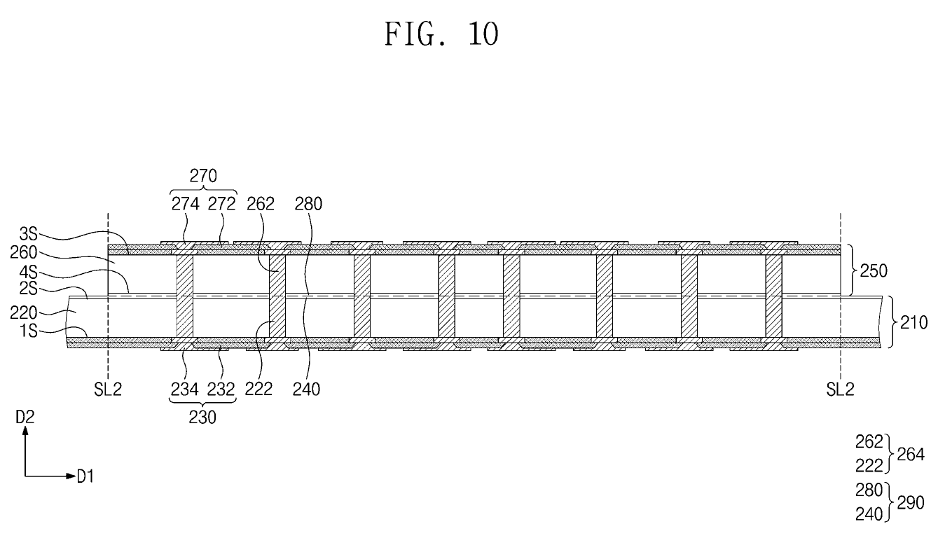

Referring to FIG. 10, the second sub-substrate 250 may be disposed on a resultant structure of FIG. 7. The second sub-substrate 250 may be hybrid bonded to the resultant structure of FIG. 7. In other words, the first sub-substrate 210 and the second sub-substrate 250 may be connected. The first insulating layer 240 and the second insulating layer 280 may be directly bonded to each other. In more detail, the first insulating layer 240 and the second insulating layer 280 may be hybrid bonded using oxide, nitride or oxynitride. The first insulating layer 240 and the second insulating layer 280 bonded to each other may have a continuous structure, and an interface between the first insulating layer 240 and the second insulating layer 280 may not be visible. For example, the first insulating layer 240 and the second insulating layer 280 may include the same material, and the first insulating layer 240 and the second insulating layer 280 may be combined and integrally formed. The first insulating layer 240 and the second insulating layer 280 may form one interposer insulating layer 290. However, the present disclosure is not limited thereto. The first insulating layer 240 and the second insulating layer 280 may include different materials and may not have a continuous structure. For example, the first insulating layer 240 and the second insulating layer 280 may each be an individual component.

The first through via 222 and the second through via 262 may be directly bonded to each other. In more detail, the first through via 222 and the second through via 262 may be hybrid bonded using copper. The first through via 222 and the second through via 262 which are bonded to each other may have a continuous structure, and an interface between the first through via 222 and the second through via 262 may not be visible. For example, the first through via 222 and the second through via 262 may include the same material, and the first through via 222 and the second through via 262 may be combined and integrally formed. The first through via 222 and the second through via 262 which are combined may form one interposer through via 264. However, the present disclosure is not limited thereto, and the first through via 222 and the second through via 262 may not have a continuous structure. For example, the first through via 222 and the second through via 262 may each be an individual component.

Thereafter, a plurality of substrates may be formed by performing a sawing process along a second sawing line SL2. The substrates which are separated from each other through the sawing process may each correspond to the interposer substrate 200 of FIG. 1.

Referring back to FIG. 1, a chip stack CS and a first semiconductor chip 300 may be mounted on the interposer substrate 200. Arrangement of the chip stack CS and the first semiconductor chip 300 may be the same as that described with reference to FIG. 1. The first semiconductor chip 300 may be mounted on the interposer substrate 200. The first semiconductor chip 300 may be aligned on the interposer substrate 200 such that first chip connection terminals 340 are arranged on first interposer substrate pads of the interposer substrate 200. The first semiconductor chip 300 may be moved close to the interposer substrate 200, and the first chip connection terminals 340 may be in contact with the first interposer substrate pads. Thereafter, a reflow process may be performed on the first chip connection terminals 340, and the first chip connection terminals 340 may connect the first semiconductor chip 300 and the interposer substrate 200.

The chip stack CS may be mounted on the interposer substrate 200 in a flip chip method. The chip stack CS may be the same as or similar to that described with reference to FIG. 1. For example, each chip stack CS may include a base chip 400, second semiconductor chips 500 stacked on the base chip 400, and a first molding layer 540 surrounding the second semiconductor chips 500. Base connection terminals 440 may be provided on a lower surface of the chip stack CS. The base connection terminals 440 may include a solder ball or a solder bump. The chip stack CS may be aligned on the interposer substrate 200 such that the base connection terminals 440 are arranged on the first interposer substrate pads. The chip stack CS may be moved close to the interposer substrate 200, and the base connection terminals 440 may be in contact with the first interposer substrate pads. Thereafter, a reflow process may be performed on the base connection terminals 440, and the base connection terminals 440 may connect the chip stack CS and the interposer substrate 200.

A second molding layer 550 surrounding the first semiconductor chip 300 and the chip stack CS on the interposer substrate 200 may be provided. The second molding layer 550 may fill a space between the chip stack CS and the first semiconductor chip 300. For example, the second molding layer 550 may be formed by applying an insulating material and then curing the insulating material. A grinding process may be performed on an upper surface of the second molding layer 550. The ground upper surface of the second molding layer 550 may have the same vertical level as that of an upper surface of the chip stack CS in a second direction D2.

Thereafter, the interposer substrate 200 may be mounted on a package substrate 100. Lower surfaces of substrate connection terminals 294 may be in contact with upper surfaces of first package substrate pads 110. The interposer substrate 200 may be electrically connected to the package substrate 100 through the substrate connection terminals 294. The chip stack CS and the first semiconductor chip 300 may be electrically connected to the package substrate 100 along the interposer substrate 200. An underfill layer 292 may be provided between the package substrate 100 and the interposer substrate 200. The underfill layer 292 may fill a space between the package substrate 100 and the interposer substrate 200 and surround the substrate connection terminals 294. The interposer substrate 200 may redistribute the chip stack CS and the first semiconductor chip 300 between the chip stack CS and the package substrate 100 and between the first semiconductor chip 300 and the package substrate 100. As described above, the semiconductor package of FIG. 1 may be manufactured.

The process of forming the second sub-substrate 250 described with reference to FIGS. 8 and 9 and the process of forming the first sub-substrate 210 described with reference to FIGS. 5-7 may be simultaneously performed. Thereafter, the interposer substrate 200 may be formed by bonding the first sub-substrate 210 and the second sub-substrate 250. The time required for a process of manufacturing the interposer substrate 200 may be reduced compared to a case of forming an upper redistribution layer on a front surface of one substrate and then forming a second redistribution layer on a rear surface of the substrate sequentially.

In addition, an interposer through via 264 of the interposer substrate 200 may be formed by bonding the first through via 222 and the second through via 262 corresponding to the first through via 222. A ratio of diameter to height of each of the first through via 222 and the second through via 264 may be about 1:5 to about 1:15. Accordingly, an aspect ratio of the interposer through via 264 which is formed by connecting the first through via 222 and the second through via 262 may be about 1:10 to about 1:30. That is, the interposer through via 264 with large aspect ratio may be formed.

In a semiconductor package, one interposer substrate may be formed by hybrid bonding two sub-substrates each having a through via. Since the through vias of the two sub-substrates are hybrid bonded, a through via with large aspect ratio may be formed. Thus, the semiconductor package with improved electrical characteristics may be provided.

In addition, in the semiconductor package, the one interposer substrate may be formed by simultaneously forming each of the two sub-substrates and then hybrid bonding the two sub-substrates. Thus, the semiconductor package with reduced manufacturing time may be provided.

In some implementations, a method for manufacturing a semiconductor package includes forming a first sub-substrate, forming a second sub-substrate, and forming an interposer substrate by connecting the first sub-substrate and the second sub-substrate, where the first sub-substrate includes a first core layer, a first redistribution layer on an upper surface of the first core layer, a first through via penetrating the first core layer, and a first insulating layer covering a lower surface of the first core layer, the second sub-substrate includes a second core layer, a second redistribution layer on a lower surface of the second core layer, a second through via penetrating the second core layer, and a second insulating layer covering an upper surface of the second core layer, and the forming of the interposer substrate includes directly bonding the first insulating layer and the second insulating layer to each other.

In some implementations, the forming of the interposer substrate may further include directly bonding the first through via and the second through via to each other.

In some implementations, the forming of the first sub-substrate and the forming of the second sub-substrate may be simultaneously performed.

In some implementations, the directly bonding of the first insulating layer and the second insulating layer may include integrally forming the first insulating layer and the second insulating layer by bonding the first insulating layer and the second insulating layer to each other.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the implementations of the present disclosure have been described with reference to the accompanying drawings, it may be understood by those skilled in the art that the present disclosure may be carried out in other specific forms without changing the technical concept or essential features. Therefore, it should be understood that the implementations described above are illustrative and non-limiting in all respects.

What is claimed is:

1. A semiconductor package comprising:
an interposer substrate; and
a first semiconductor chip on an upper surface of the interposer substrate,
wherein the interposer substrate includes a first sub-substrate and a second sub-substrate, and the second sub-substrate contacts the first sub-substrate along a vertical direction,
wherein the first sub-substrate includes
a first core layer having a first surface and a second surface,
a first through via extending through the first core layer and having a diameter that decreases toward the second surface of the first core layer, and
a first redistribution layer on the first surface of the first core layer,
wherein the second sub-substrate includes
a second core layer having a third surface and a fourth surface,
a second through via extending through the second core layer and having a diameter that decreases toward the fourth surface of the second core layer, and
a second redistribution layer on the third surface of the second core layer,
wherein the second surface of the first core layer and the fourth surface of the second core layer face each other, and
wherein the first through via contacts the second through via along the vertical direction.

2. The semiconductor package of claim 1, wherein the first through via protrudes above the second surface of the first core layer, and
wherein the second through via protrudes above the fourth surface of the second core layer.

3. The semiconductor package of claim 2, wherein the interposer substrate comprises an interposer insulating layer filling a space between the first core layer and the second core layer, and
wherein the interposer insulating layer surrounds the first through via and the second through via between the first core layer and the second core layer.

4. The semiconductor package of claim 3, wherein the interposer insulating layer comprises:
a first insulating layer covering the second surface of the first core layer; and
a second insulating layer covering the fourth surface of the second core layer, and
wherein the first insulating layer contacts the second insulating layer.

5. The semiconductor package of claim 4, wherein a diameter of a lower surface of the first through via and a diameter of an upper surface of the second through via are different at a contact surface between the first insulating layer and the second insulating layer.

6. The semiconductor package of claim 1, comprising a substrate connection terminal on a lower surface of the second redistribution layer,
wherein the first redistribution layer is electrically connected to the substrate connection terminal through the first through via, the second through via, and the second redistribution layer.

7. The semiconductor package of claim 1, comprising:
a chip stack disposed on the upper surface of the interposer substrate, the chip stack being spaced apart from the first semiconductor chip along a horizontal direction;
a molding layer surrounding the chip stack and the first semiconductor chip on the upper surface of the interposer substrate; and
a package substrate on a lower surface of the interposer substrate.

8. The semiconductor package of claim 1, wherein the first redistribution layer comprises a first insulating pattern and a first wiring pattern on the first insulating pattern,
wherein the second redistribution layer comprises a second insulating pattern and a second wiring pattern on the second insulating pattern, and
wherein the first wiring pattern is electrically connected to the second wiring pattern through the first through via and the second through via.

9. A semiconductor package comprising:
an interposer substrate; and
a first semiconductor chip on an upper surface of the interposer substrate,
wherein the interposer substrate includes
a first core layer,
a first redistribution layer on an upper surface of the first core layer,
a second core layer on a lower surface of the first core layer,
a second redistribution layer on a lower surface of the second core layer,
an interposer through via extending through the first core layer and the second core layer, and
an interposer insulating layer interposed between the first core layer and the second core layer.

10. The semiconductor package of claim 9, wherein the interposer through via comprises:
a first through via extending through the first core layer and protruding on to the lower surface of the first core layer; and
a second through via extending through the second core layer and protruding on to an upper surface of the second core layer, and
wherein the first through via contacts the second through via between the first core layer and the second core layer.

11. The semiconductor package of claim 10, wherein a diameter of a lower surface of the first through via and a diameter of an upper surface of the second through via are different at a contact surface between the first through via and the second through via.

12. The semiconductor package of claim 10, wherein the interposer insulating layer fills a space between the first core layer and the second core layer, and the interposer insulating layer surrounds the first through via and the second through via.

13. The semiconductor package of claim 10, wherein a diameter of the first through via decreases toward the second through via, and
wherein a diameter of the second through via decreases toward the first through via.

14. The semiconductor package of claim 9, wherein a height of the first core layer is same as a height of the second core layer.

15. The semiconductor package of claim 9, wherein a ratio of diameter to height of the interposer through via is in a range between 1:30 and 1:10.

16. A semiconductor package comprising:
a package substrate;
an interposer substrate on an upper surface of the package substrate; and
a first semiconductor chip on an upper surface of the interposer substrate,
wherein the interposer substrate includes
a first core layer,
a first redistribution layer on an upper surface of the first core layer,
a first through via extending through the first core layer and protruding on to a lower surface of the first core layer,
a second core layer on the lower surface of the first core layer,
a second redistribution layer on a lower surface of the second core layer,
a second through via extending through the second core layer and protruding on to an upper surface of the second core layer, and
an interposer insulating layer filling a space between the first core layer and the second core layer, and
wherein the first through via contacts the second through via between the first core layer and the second core layer.

17. The semiconductor package of claim 16, wherein a height of the interposer insulating layer in a direction perpendicular to the upper surface of the interposer substrate is in a range between 0.1 micrometers and 3 micrometers.

18. The semiconductor package of claim 16, wherein a diameter of the first through via decreases toward the second through via, and
wherein a diameter of the second through via decreases toward the first through via.

19. The semiconductor package of claim 16, comprising:
a chip stack disposed on the upper surface of the interposer substrate, the chip stack being spaced apart from the first semiconductor chip along a horizontal direction; and
a molding layer surrounding the chip stack and the first semiconductor chip on the upper surface of the interposer substrate.

20. The semiconductor package of claim 16, wherein the interposer insulating layer comprises:
a first insulating layer covering the lower surface of the first core layer; and
a second insulating layer covering the upper surface of the second core layer, and
wherein the first insulating layer contacts the second insulating layer.
